(19) United States
(12) Patent Application Publication
(10) Pub. No.: US 2025/0231268 A1
(43) Pub. Date: Jul. 17, 2025

(54) High-bandwidth Vector Network Analyzer System for Transmitting and Receiving Vector Signals

(71) Applicant: TRANSCOM (SHANGHAI) TECHNOLOGY CO., LTD., Shanghai (CN)

(72) Inventors: Shuang CHEN, Shanghai (CN); Xiaolei WANG, Shanghai (CN)

(21) Appl. No.: 18/730,720

(22) PCT Filed: Jul. 21, 2022
(86) PCT No.: PCT/CN2022/106994

§ 371 Date: Jul. 19, 2024

(30) Foreign Application Priority Data
Jan. 21, 2022 (CN) 202210070814.7

(51) Int. Cl. G01R 35/00; G01R 27/32; G01R 29/10; H04B 1/00

(52) U.S. Cl. CPC G01R 35/005; G01R 29/10; H04B 1/0096; G01R 27/32

(57) ABSTRACT

A high-bandwidth vector network analyzer system for transmitting and receiving vector signals includes a transmitting channel and a receiving channel, transmitting channel including a multi-tone signal circuit structure, an input of the multi-tone signal circuit structure being connected to a digital signal processing module, the multi-tone signal circuit structure generating a multi-tone parallel signal and outputting a multi-tone RF signal to a receiving end; receiving channel including multi-channel parallel digital downconverters group, the multi-channel parallel digital downconverters group including a plurality of multi-channel parallel digital downconverters, the inputs of the plurality of multi-channel parallel digital downconverters are respectively connected to a plurality of analogue-to-digital conversion modules, and processing the plurality of audio signals in parallel.

### CROSS-REFERENCE TO RELATED APPLICATION

This application claims priority of Chinese Invention patent application No. 202210070814.7 filed Jan. 21, 2022, which is incorporated herein by reference.

### FIELD OF TECHNOLOGY

The present invention relates to the field of communication equipment, in particular to the field of vector network analyzer, specifically, it refers to a high-bandwidth vector network analyzer system for transmitting and receiving vector signals.

### DESCRIPTION OF RELATED ARTS

Vector network analyzer is a test equipment for measuring S-parameters of RF/microwave components with a wide range of applications. It usually consists of an equipment that locally generates a continuous wave signal of known frequency, which is output through a measurement port and, after passing through the DUT (Device Under Test), is returned to the equipment, where the S-parameters of the DUT are calculated by measuring the amplitude and phase changes of the signal.

The principle of a typical vector signal generator is shown in FIG. 1, which mainly consists of an RF source (RFS), a local oscillator (LO), a dual directional coupler (COUP), and a four-channel receiver. The RF source generates a sinusoidal signal with adjustable frequency, which can be output to Port A (Port A) or Port B (Port B) after switching (SW1) and amplification, and the dual directional coupler can extract the reference signal and the incident signal at the same time, and then enter the ADC for analogue-to-digital conversion after mixing, filtering, and amplification, and then carry out the digital signal processing of the multiple signals in the DSP, including digital down-conversion, digital filtering, extraction, calculation of signal amplitude, phase information, and error correction to obtain the final measurement result—the S-parameters of the measured parts.

In the above measurement principle, the RF source needs to produce a signal that is a sine wave signal, and in essence, the individual receivers are a narrow-band measurement system, this is because the system only needs to process the CW signal, and to obtain test results for a certain frequency range, the RF source needs to constantly switch the output frequency. Frequency switching requires a certain amount of time to achieve a stable signal output result. Therefore, the measurement speed is affected by the signal transmission rate, digital signal processing speed and other factors, in fact, the main factor is the frequency switching time of the RF source. In summary, the traditional vector network analyzer has the following limitations:
Firstly, in test scenarios where test efficiency is a priority, it is difficult to obtain a significant increase in test speed with the existing scheme. For the test of multiple frequency points, it is necessary to set up the RF source and the local oscillator synchronously, and complete the test by step scanning. Because the frequency switching between the local oscillator and the RF source requires a certain stabilization time, this is a physical process that cannot be broken through.
Secondly, as an equipment with an integrated transceiver function, it only supports continuous wave signal processing due to the design principle of narrow-band measurement and the implementation principle of vector network analysis. The whole equipment does not have the ability to process vector signals, especially large bandwidth signals. Usually, these tests require other specialized equipment to support.
Thirdly, the industrialized testing of communications, semiconductors, etc., requires that the testing speed and functional integration of equipment be constantly improved. It is difficult to expand the functions on the existing basis, and only some of the equipment is currently integrated with the function of spectrum analysis. More complex test functions cannot be achieved. Such as cross-talk test, response speed, rise time, EVM test, etc., In this aspect, in response to the above problem, a novel vector network analyzer equipment and method with high broadband processing capability is proposed, which has a large bandwidth vector signal processing capability in addition to the capability of a traditional vector network analyzer, as well as a parallel signal processing capability, which greatly enhances the testing speed. And the technical architecture of the equipment brings about greatly enhanced reusability of the equipment and increased functional expansion capability.

### SUMMARY OF THE INVENTION

It is an object of the present invention to overcome the drawbacks of the above-mentioned prior art, and to provide a high-bandwidth vector network analyzer system that meets the requirements of fast testing speed, strong equipment reusability, and a wider range of applicability for realizing transmitting and receiving vector signals.

In order to achieve the above purpose, the high bandwidth vector network analyzer system of the present invention for implementing vector signal transceiver is as follows:
The high-bandwidth vector network analyzer system for transmitting and receiving vector signals, the main feature of which is that said system comprises a transmitting channel, the said transmitting channel comprising a multi-tone signal circuit structure, an input of the multi-tone signal circuit structure being connected to a digital signal processing module, the multi-tone signal circuit structure generating a multi-tone parallel signal and outputting a multi-tone RF signal to a receiving end;
the said system further comprises a receiving channel, the said receiving channel comprising multi-channel parallel digital downconverters group, the multi-channel parallel digital downconverters group comprising a plurality of multi-channel parallel digital downconverters, the inputs of the plurality of multi-channel parallel digital downconverters are respectively connected to a plurality of analogue-to-digital conversion modules, and processing the plurality of audio signals in parallel.

Preferably, the multi-tone signal circuit structure comprises a multi-tone signal generator, a two-way multi-tone signal processing circuit structure and an adder, the said multi-tone signal generator having an input connected to a digital signal processing module generating multi-tone parallel signals at the digital end to produce an I-way baseband signal and a Q-way baseband signal, the said two-way multi-tone signal processing circuit structure receives the I-way baseband signal and Q-way baseband signal, respectively, and performs multi-tone signal processing, and said adder receives the signals output from the two-way multi-tone signal processing circuit structure, adds the signals and outputs a multi-tone radio frequency signal.

Preferably, the said two-way multi-tone signal processing circuit structure comprises a digital-to-analogue converter, a modulator and a mixer, respectively, the digital-to-analogue converter of the said two-way multi-tone signal processing circuit structure receives I-way baseband signals and Q-way baseband signals, respectively, said modulator's input is connected to the said digital-to-analogue converter, the said mixer's input receives the signals of the output of the modulator as well as the signals of the local radio frequency source, and carries out the frequency mixing, both of the mixed signals of the said two-way multi-tone signal processing circuit structure being output to said adder.

Preferably, the said receiving channel further comprises a memory module, the outputs of the said multi-channel parallel digital downconverters are connected to the said memory module, and the outputs of the said memory module are connected to the said digital signal processing module.

Preferably, the multi-channel parallel digital downconverters comprises N groups of digital downconverter modules, the N groups of digital downconverter modules connected in parallel, each of the said groups of digital downconverter modules comprising a digital oscillator, a first multiplier, a second multiplier, a first FIR digital extraction filter and a second FIR digital extraction filter, the said digital oscillator outputs 2 channels of IQ baseband data to a first multiplier and a second multiplier, respectively, and the said first multiplier and second multiplier both receive signals from an analogue-to-digital converter module, and the output of the first multiplier is connected to the first FIR digital extraction filter, and the output of the second multiplier is connected to the second FIR digital extraction filter, and the first FIR digital extraction filter and the second FIR digital extraction filter output I-way and Q-way signals respectively.

Preferably, the said receiving channel further comprises a fast Fourier transform module group, the fast Fourier transform module group comprising a plurality of fast Fourier transform modules, the inputs of the said plurality of fast Fourier transform modules are respectively connected to a plurality of analogue-to-digital conversion modules, and the outputs of said plurality of fast Fourier transform modules are all connected to a memory module.

Preferably, where the number of the said digital downconverter modules is less than the number of channels of the multi-tone signal processing circuit structure, the said system is multiplexed using time-shared serial processing.

Preferably, the output frequency of the said digital oscillator is defined according to the measured frequency.

With the high-bandwidth vector network analyzer system of the present invention that implements vector signal transmitting and receiving, the test speed of multi-frequency points is greatly improved, and the test speed can be increased by more than 10-20 times in typical scenarios. It is very practical for the occasions with high testing efficiency requirements; strong functionality scalability, making the traditional vector network analyzer with the function of vector signal transmitting and receiving, and able to realize the testing tasks that cannot be completed by the traditional vector network analyzer, with a certain increase in the complexity and cost of the hardware.

### BRIEF DESCRIPTION OF THE DRAWINGS

FIG. 1 shows a block diagram of a prior art two-port vector network analyzer.

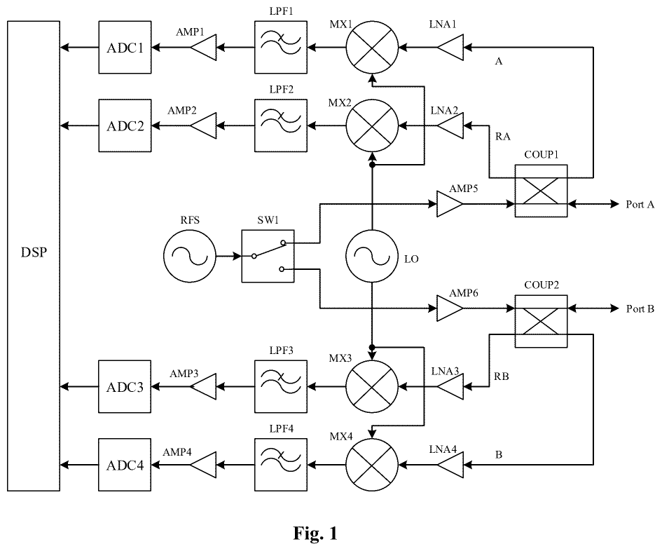

FIG. 2 shows a schematic diagram of the circuit structure of the high bandwidth vector network analyzer system of the present invention for implementing vector signal transceivers.

FIG. 3 shows a schematic diagram of the circuit structure of a multi-channel parallel digital downconverter of the high bandwidth vector network analyzer system of the present invention implementing vector signal transceivers.

FIG. 4 shows a schematic diagram of the circuit structure of the high bandwidth vector network analyzer system of the present invention for implementing vector signal transceivers by means of a fast Fourier transform module in place of a multi-channel parallel digital downconverter.

### DETAILED DESCRIPTION OF THE PREFERRED EMBODIMENT

In order to be able to understand the technical content of the present invention more clearly, is further exemplified by the following detailed description of embodiments.

The high-bandwidth vector network analyzer system for transmitting and receiving vector signals of the present invention, wherein comprises a transmitting channel, the said transmitting channel comprising a multi-tone signal circuit structure, an input of the multi-tone signal circuit structure being connected to a digital signal processing module, the multi-tone signal circuit structure generating a multi-tone parallel signal and outputting a multi-tone RF signal to a receiving end;

the said system further comprises a receiving channel, the said receiving channel comprising multi-channel parallel digital downconverters group, the multi-channel parallel digital downconverters group comprising a plurality of multi-channel parallel digital downconverters, the inputs of the plurality of multi-channel parallel digital downconverters are respectively connected to a plurality of analogue-to-digital conversion modules, and processing the plurality of audio signals in parallel.

As a preferred embodiment of the present invention, the multi-tone signal circuit structure comprises a multi-tone signal generator, a two-way multi-tone signal processing circuit structure and an adder, the said multi-tone signal generator having an input connected to a digital signal processing module generating multi-tone parallel signals at the digital end to produce an I-way baseband signal and a Q-way baseband signal, the said two-way multi-tone signal processing circuit structure receives the I-way baseband signal and Q-way baseband signal, respectively, and performs multi-tone signal processing, and said adder receives the signals output from the two-way multi-tone signal processing circuit structure, adds the signals and outputs a multi-tone radio frequency signal.

As a preferred embodiment of the present invention, the said two-way multi-tone signal processing circuit structure comprises a digital-to-analogue converter, a modulator and a mixer, respectively, the digital-to-analogue converter of the said two-way multi-tone signal processing circuit structure receives I-way baseband signals and Q-way baseband signals, respectively, said modulator's input is connected to the said digital-to-analogue converter, the said mixer's input receives the signals of the output of the modulator as well as the signals of the local radio frequency source, and carries out the frequency mixing, both of the mixed signals of the said two-way multi-tone signal processing circuit structure being output to said adder.

As a preferred embodiment of the present invention, the said receiving channel further comprises a memory module, the outputs of the said multi-channel parallel digital downconverters are connected to the said memory module, and the outputs of the said memory module are connected to the said digital signal processing module.

As a preferred embodiment of the present invention, the multi-channel parallel digital downconverters comprises N groups of digital downconverter modules, the N groups of digital downconverter modules connected in parallel, each of the said groups of digital downconverter modules comprising a digital oscillator, a first multiplier, a second multiplier, a first FIR digital extraction filter and a second FIR digital extraction filter, the said digital oscillator outputs 2 channels of IQ baseband data to a first multiplier and a second multiplier, respectively, and the said first multiplier and second multiplier both receive signals from an analogue-to-digital converter module, and the output of the first multiplier is connected to the first FIR digital extraction filter, and the output of the second multiplier is connected to the second FIR digital extraction filter, and the first FIR digital extraction filter and the second FIR digital extraction filter output I-way and Q-way signals respectively.

As a preferred embodiment of the present invention, the said receiving channel further comprises a fast Fourier transform module group, the fast Fourier transform module group comprising a plurality of fast Fourier transform modules, the inputs of the said plurality of fast Fourier transform modules are respectively connected to a plurality of analogue-to-digital conversion modules, and the outputs of said plurality of fast Fourier transform modules are all connected to a memory module.

As a preferred embodiment of the present invention, where the number of the said digital downconverter modules is less than the number of channels of the multi-tone signal processing circuit structure, the said system is multiplexed using time-shared serial processing.

As a preferred embodiment of the present invention, the output frequency of the said digital oscillator is defined according to the measured frequency.

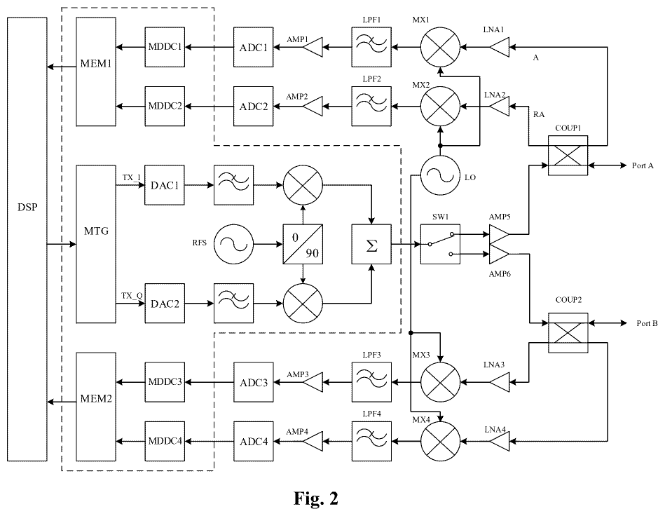

In a specific embodiment of the present invention, a system block diagram and connection relationship of the present invention is shown in FIG. 2, the working principle and method of the present invention are described as follows:

For simultaneous receiving and transmitting channels with parallel multi-signal capability, increasing the number of channels is usually used, but this method increases the number of channels by a limited amount, and the increase in hardware brings about a deterioration in complexity, cost, and reliability. Vector modulation has the ability to concurrently concur multi-tone signals, therefore, the present invention improves the transmitting and receiving channels, all in the transmitting and receiving mode of vector modulation demodulation, and the dotted box in FIG. 2 shows the additions and changes made by the present invention.

At the transmitter end, the multi-tone signal generator (MTG) generates multi-tone parallel signals at the digital end, generates I/Q two-way baseband signals, outputs two-way I and Q road signals after the DAC respectively, and then mixes and sums them with the local RF source through the modulator respectively, to produce the final output multi-tone RF signals, and the number of output multi-tone signals is generated by the equipment according to the test needs, but the total bandwidth of the multi-tone signals generated at each time should not be greater than the modulation bandwidth of the digital baseband, which in turn usually depends on the adoption rate of the DAC.

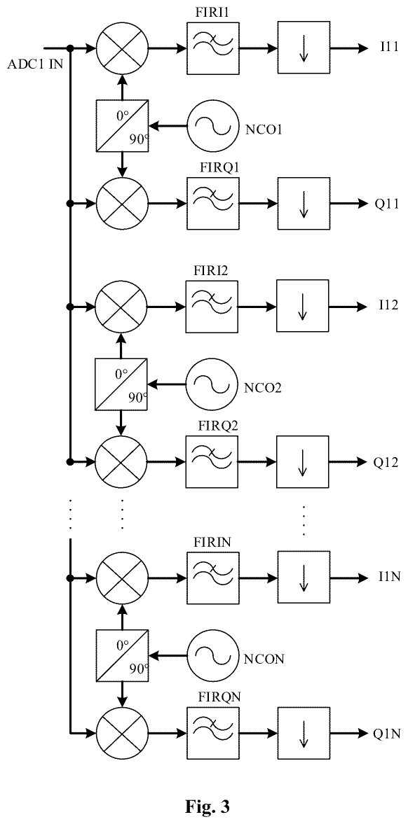

At the receiving end, the previous processing flow is basically the same. However, due to the increase of signal bandwidth, the RF channel bandwidth of the whole receiving part should meet the requirements of the transmitting bandwidth, and usually the two are kept consistent. If the modulation bandwidth of the transmitting channel is 100 MHz, then all units of the receiving channel should ensure the signal bandwidth of 100 MHz, including the selection of the IF after mixing, and also ensure that the 100 MHz bandwidth signal can pass. At the same time, the ADC needs to increase the sampling rate to ensure that no aliasing occurs. In addition to the change of bandwidth and sampling rate, the digital signal after the ADC enters the Multiple Parallel Digital Downconverter (MDDC), which can process multiple audio signals in parallel, and its working principle is shown in FIG. 3:

The principle of operation of the multiplexed digital downconverter is shown in FIG. 3, which consists of N groups of parallel digital downconverters, each group consisting of two multipliers, digital oscillator (NCO), and two FIR digital extraction filters. The output frequency of the NCO is determined by the measurement frequency and can be defined programmatically, each group outputs the IQ baseband data of 2 signals for the DSP to calculate the amplitude and phase of the signals, the number of N depends on the resource capability of the hardware and the complexity of the system, which needs to be considered comprehensively in the realization process. When the number of N is less than the number of multi-tone signals, multiplexing can be performed using time-shared serial processing.

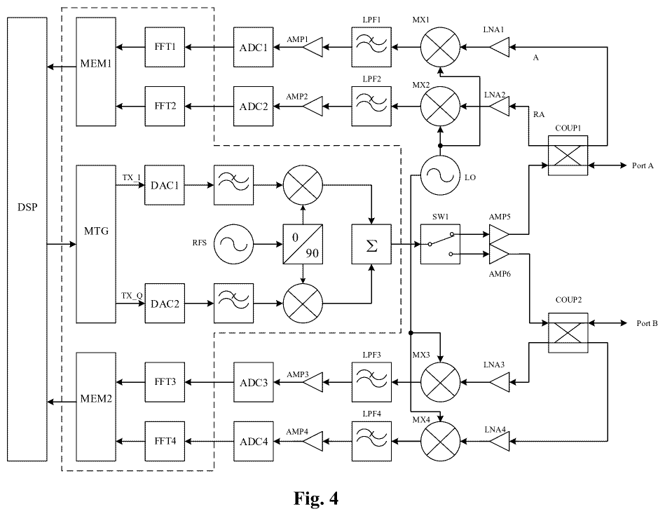

The use of multi-channel digital down-conversion can be used to extract the signal under test accurately, avoiding the test interference generated by the presence of other frequency signals, with high accuracy, but also requiring high hardware resources. When the test dynamic range and fluctuation requirements are not high, the circuit structure shown in FIG. 4 can be used for direct FFT measurements, i.e., the signal is processed by FFT directly after the ADC to obtain the amplitude and phase information of each frequency point, which is stored for measurement, so as to obtain a higher test speed and not be affected by resources.

This present invention adopts the technical architecture of vector signal transceiver to realize the measurement of vector network analysis, which can complete some more complicated tests due to the capability of vector transceiver. For example, by using a DAC to output RF pulse signals, it is possible to carry out time-domain testing of the DUT, which is not possible with conventional vector network analyzers.

With the high-bandwidth vector network analyzer system of the present invention that implements vector signal transmitting and receiving, the test speed of multi-frequency points is greatly improved, and the test speed can be increased by more than 10-20 times in typical scenarios. It is very practical for the occasions with high testing efficiency requirements; strong functionality scalability, making the traditional vector network analyzer with the function of vector signal transmitting and receiving, and able to realize the testing tasks that cannot be completed by the traditional vector network analyzer, with a certain increase in the complexity and cost of the hardware.

In this specification, the present invention has been described with the reference to its specific embodiments. However, it is obvious still may be made without departing from the spirit and scope of the present invention, various modifications and transformation. Accordingly, the specification and drawings should be considered as illustrative rather than restrictive.

1. A high-bandwidth vector network analyzer system for transmitting and receiving vector signals, the system comprising a transmitting channel, the transmitting channel comprising a multi-tone signal circuit structure, an input of the multi-tone signal circuit structure being connected to a digital signal processing module, the multi-tone signal circuit structure generating a multi-tone parallel signal and outputting a multi-tone RF signal to a receiving end;
wherein the system further comprises a receiving channel, the receiving channel comprising multi-channel parallel digital downconverters group, the multi-channel parallel digital downconverters group comprising a plurality of multi-channel parallel digital downconverters, the inputs of the plurality of multi-channel parallel digital downconverters are respectively connected to a plurality of analogue-to-digital conversion modules, and processing the plurality of audio signals in parallel.

2. The high-bandwidth vector network analyzer system for transmitting and receiving vector signals according to claim 1, wherein the multi-tone signal circuit structure comprises a multi-tone signal generator, a two-way multi-tone signal processing circuit structure and an adder, the multi-tone signal generator having an input connected to a digital signal processing module generating multi-tone parallel signals at the digital end to produce an I-way baseband signal and a Q-way baseband signal, the two-way multi-tone signal processing circuit structure receives the I-way baseband signal and Q-way baseband signal, respectively, and performs multi-tone signal processing, and said adder receives the signals output from the two-way multi-tone signal processing circuit structure, adds the signals and outputs a multi-tone radio frequency signal.

3. The high-bandwidth vector network analyzer system for transmitting and receiving vector signals according to claim 2, wherein the two-way multi-tone signal processing circuit structure comprises a digital-to-analogue converter, a modulator and a mixer, respectively, the digital-to-analogue converter of the two-way multi-tone signal processing circuit structure receives I-way baseband signals and Q-way baseband signals, respectively, said modulator's input is connected to the digital-to-analogue converter, the mixer's input receives the signals of the output of the modulator as well as the signals of the local radio frequency source, and carries out the frequency mixing, both of the mixed signals of the two-way multi-tone signal processing circuit structure being output to said adder.

4. The high-bandwidth vector network analyzer system for transmitting and receiving vector signals according to claim 1, wherein the receiving channel further comprises a memory module, the outputs of the multi-channel parallel digital downconverters are connected to the memory module, and the outputs of the memory module are connected to the said digital signal processing module.

5. The high-bandwidth vector network analyzer system for transmitting and receiving vector signals according to claim 1, wherein the multi-channel parallel digital downconverters comprises N groups of digital downconverter modules, the N groups of digital downconverter modules connected in parallel, each of the groups of digital downconverter modules comprising a digital oscillator, a first multiplier, a second multiplier, a first FIR digital extraction filter and a second FIR digital extraction filter, the digital oscillator outputs 2 channels of IQ baseband data to a first multiplier and a second multiplier, respectively, and the first multiplier and second multiplier both receive signals from an analogue-to-digital converter module, and the output of the first multiplier is connected to the first FIR digital extraction filter, and the output of the second multiplier is connected to the second FIR digital extraction filter, and the first FIR digital extraction filter and the second FIR digital extraction filter output I-way and Q-way signals respectively.

6. The high-bandwidth vector network analyzer system for transmitting and receiving vector signals according to claim 1, wherein the receiving channel further comprises a fast Fourier transform module group, the fast Fourier transform module group comprising a plurality of fast Fourier transform modules, the inputs of the plurality of fast Fourier transform modules are respectively connected to a plurality of analogue-to-digital conversion modules, and the outputs of said plurality of fast Fourier transform modules are all connected to a memory module.

7. The high-bandwidth vector network analyzer system for transmitting and receiving vector signals according to claim 5, wherein where the number of the digital downconverter modules is less than the number of channels of the multi-tone signal processing circuit structure, the system is multiplexed using time-shared serial processing.

8. The high-bandwidth vector network analyzer system for transmitting and receiving vector signals according to claim 5, wherein the output frequency of the digital oscillator is defined according to the measured frequency.
